(19) United States
(12) Patent Application Publication
(10) Pub. No.: US 2012/0027946 A1
(43) Pub. Date: Feb. 2, 2012

(54) DIRECT DEPOSIT AND REMOVAL OF NANOSCALE CONDUCTORS

(76) Inventors: Adam V. Steele, (US); Brenton J. Knuffman, (US); Jabez J. McClelland, (US)

(21) Appl. No.: 13/252,613

(22) Filed: Oct. 4, 2011

Related U.S. Application Data
(60) Provisional application No. 61/415,525, filed on Nov. 19, 2010.

(51) Int. Cl. C23C 14/42; C23C 14/46

(52) U.S. Cl. 427/524; 118/723 FI; 204/192.34

(57) ABSTRACT

A method and apparatus for depositing and removing nanoscale conductors. A magneto-optical trap ion source (MOTIS) creates a beam of focused metal ions that either deposit directly at low energy (<0.5 keV) or sputter material away at high energy (>2 keV). By scanning the beam, layers of material may be built up into a desired pattern. By employing a MOTIS as the source of ions for the beam, and then directing that beam through an appropriate ion-optical column, isotopically pure samples may be deposited into patterns with nanoscale feature sizes. The ability to quickly remove material, and deposit isotopically pure metals is desirable, for instance, during the circuit edit stage of integrated circuit manufacture.

### CROSS-REFERENCE TO RELATED APPLICATIONS

The present application claims priority to provisional application Ser. No. 61/415,525, filed on or about Nov. 19, 2010, entitled “Method and Apparatus for Direct Deposit and Removal of Nanoscale Conductors” naming the same inventors as in the present application. The contents of this provisional application are incorporated by reference, the same as if fully set forth.

### STATEMENT REGARDING FEDERALLY SPONSORED RESEARCH/DEVELOPMENT

The subject matter of this patent application was invented under the support of at least one United States Government contract. Accordingly, the United States Government may manufacture and use the invention for governmental purposes without the payment of any royalties.

### BACKGROUND OF THE INVENTION

1. Field of Invention

The present disclosure relates to nanoscale conductors and, more particularly, to deposition and removal of conductive material at the nanoscale level.

2. Description of Related Art

The deposit and removal of conductive traces in nanoscale conductors is of importance in various fields. For example, in the field of integrated circuit editing, current circuit edit practice may involve using a high energy (30 keV) gallium ion beam to add and remove conductive traces in integrated circuits. This addition and removal may be performed as part of the manufacturing debugging process.

Material removal may be achieved by direct sputtering with the ion beam, or by ion-induced chemistry with precursor gases, resulting in local etching of the surface.

Focused ion beams have been used for direct deposition of nanoscale conductors. However, there have been difficulties associated with direct focused ion beam (FIB) deposition of nanoscale conductors, which has led to the development of FIB-induced chemical vapor deposition (CVD) as an alternative to direct deposition, as discussed in U.S. Pat. No. 5,104,684. In this technique, the target surface may be exposed to a gaseous precursor compound, which contains the desired deposition metal, as it is bombarded by the ion beam. The technique can produce yields of about one metal atom on the surface per ion in the beam. The width of a line of material deposited in this way is roughly equal to the size of the trenches which can be milled into the target with the same beam (in the absence of the precursor).

Several disadvantages may be associated with this technique. The deposited material is typically less than fifty percent (50%) metal precursor by atom count, with the balance consisting of ions from the focused beam and other elements in the precursor compound. As a result, the conductivity of the deposited material is lower by a factor of 10 to 100 than that of the bulk metal. Additionally, since the technique is often performed at high beam energies (>2 keV) in order achieve a small focal spot size, large quantities of beam ions are implanted into the target below the surface to depths on the order of 10 nanometers. This unwanted contamination can be a problem during circuit editing processes since they often take place very close to circuit components which must not be damaged.

Other problems may occur with current circuit edit practice. For example, during the chemical deposition process, careful balancing of beam chemistry (which adds material) and sputtering by high energy gallium ions (which removes material) must be exercised. This makes it difficult to develop robust processes. There is further a need for deposition and removal of nanoscale conductors that does not require balancing of beam chemistry.

In addition, circuit editing may require a careful deposition or removal of material very close to other materials. It may be desirable that these other materials are not damaged. Accordingly, there is yet further a need for deposition and removal of nanoscale conductors that reduces or eliminates damage to other materials when adding or removing material very close to the other material.

### BRIEF SUMMARY OF DISCLOSURE

The present disclosure addresses the needs described above by providing a method and apparatus for deposition and removal of nanoscale conductors. The apparatus comprises a focused ion beam source, including a magneto-optical trap ion source; and a beam energy control device configured to selectively and controllably produce a low energy beam, the energy control device being further configured to selectively and controllably produce a high energy beam. The apparatus further comprises an ion-optical column configured to receive the beam from the beam energy control device and direct the low energy beam onto the target surface in order to deposit nanoscale conductive material onto the target surface, the ion optical column being further configured to direct the high energy beam onto the target surface in order to remove nanoscale conductive material from the target surface.

The method comprises the steps of providing a focused ion beam from a source that includes a magneto-optical trap ion source. The method further comprises receiving the focused ion beam at a beam energy control device and selectively and controllably producing a low energy beam with the beam energy control device and/or selectively and controllably producing a high energy beam with the beam energy control device. The method still further comprises directing the low energy beam from an ion optical column onto the target surface in order to deposit nanoscale conductive material onto the target surface, and/or directing the high energy beam from an ion optical column onto the target surface in order to remove nanoscale conductive material from the target surface.

These, as well as other objects, features and benefits will now become clear from a review of the following detailed description of illustrative embodiments and the accompanying drawings.

### BRIEF DESCRIPTION OF DRAWINGS

FIG. 1 is an apparatus for direct deposit and removal of nanoscale conductors in accordance with one embodiment of the present disclosure.

FIGS. 2A, 2B, 2C and 2D illustrate the apparatus of FIG. 1 when applied to creation of a vertical interconnect in accordance with one embodiment of the present disclosure.

FIG. 3 is a magneto-optical trap ion source in accordance with one embodiment of the disclosure.

### DETAILED DESCRIPTION OF THE DISCLOSURE

An apparatus is described for direct deposition and removal of nanoscale conductors onto a target surface such as a substrate. The apparatus may include magneto-optical trap ion source (MOTIS) combined with a number of well-known ion-optical elements to produce a beam of focused metal ions that form nanoscale conductive material. The focused ion beam may be capable of selective rapid and simple switching between deposition and removal of conductive material. The focused metal ions may either deposit directly at low energy or sputter material away at high energy. The beam energy may be controlled such that it is of a particular energy within the low energy or high energy spectrum. The size of the features which can be produced by these techniques will be similar in size to that of the ion beam at the target.

For purposes of the present disclosure, included within the definition of conductive materials are any one of lithium (Li), sodium (Na), potassium (K), rubidium (Rb), cesium (Cs), magnesium (Mg), calcium (Ca), strontium (Sr), barium (Ba), chromium (Cr), silver (Ag), erbium (Er), aluminum (Al), dysprosium (Dy) and ytterbium (Yb). Generally, a conductive material may be defined herein as one having a conductivity of 10⁶ Siemens per meter (S/m) or greater.

The ions needed to deposit and remove nanoscale conductors may be created with kinetic energies ranging from less than 0.5 keV (low energy) to greater than 2 keV (high energy), and may be focused to nanometer-scale dimensions and directed at a surface. When the ions have a low kinetic energy, i.e., energy less than about 0.5 keV, they may deposit directly on the surface in a spot with nanoscale dimensions, thus leaving a small quantity of conductive material on the surface. When this deposition spot is scanned across a surface, a pattern of arbitrary design may be created in directly deposited conductive material. When the ions have a high kinetic energy, i.e., energy greater than about 2 keV, the metal ions may sputter more material from the surface than is deposited. Using the same scanning methods as in the deposition process, it may be possible to remove existing conductive patterns from the surface.

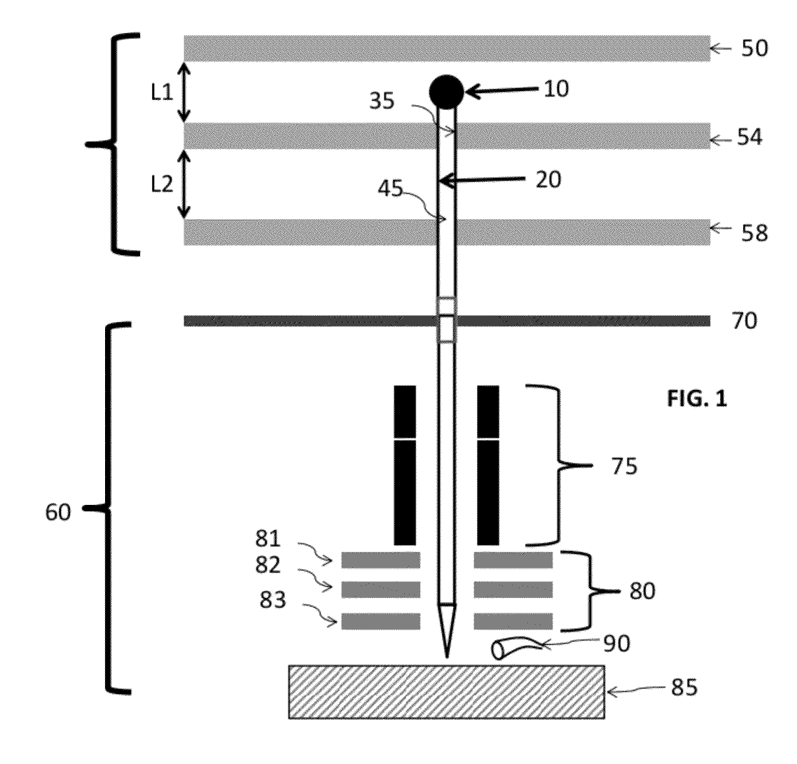

Referring now to FIG. 1, illustrated is an apparatus for deposit and removal of nanoscale conductors in accordance with one embodiment of the present disclosure. Ions may be produced by the MOTIS 10. Unlike other high-brightness, low-emittance ion sources, the MOTIS 10 may provide a choice of ionic species, several of which may be suitable for direct deposition of conductive material, e.g., those mentioned hereinabove. Also, because the energy spread in the MOTIS 10 may be proportional to the acceleration energy, chromatic aberrations in the ion focusing optics may be constant over the entire range of beam energies. Therefore, both low and high energy beams may be easy to create using the same apparatus. Thus, rapid switching between deposition and removal may be possible, greatly reducing the total beam time required for a given task.

In lieu of a MOTIS 10, other ion sources may be used when a high current, low resolution source is needed. This type of ion source may be needed for fine editing of small circuit components over large areas. Where an ionic species not provided by the MOTIS 10 is needed, another ion source may also be used. For example, it may be that the desired conductive material (e.g., gold or platinum) is not compatible with use in a MOTIS 10. It should be noted, however, that the MOTIS 10 may indeed offer a much broader choice than conventional ion sources.

After ions are produced by the MOTIS 10, they may be accelerated by the electric field created by the difference in electric potential Vₜₒₚ−V_{mid}. The beam 20 may then experience lensing action as it passes through apertures in each of the middle electrode 54 and bottom electrode 58. More particularly, beam 20 may experience defocusing and/or focusing as it passes an aperture 35 in the middle electrode 54.

Beam 20 may also experience defocusing and/or focusing as it passes through the aperture 45 in the bottom electrode 58. The actual lensing action experienced by the beam as it passes through aperture 45 will depend on the differences in the electric field in the space between top electrode 50 and middle electrode 54 and the field in the space between middle electrode 54 and bottom electrode 58. If these fields are the same, then there may be no lensing action. If the fields are different then there may be lensing action. The electric fields arise as a function of voltage differences between the electrodes. For example, the electric field in the space between top electrode 50 and middle electrode 54 separated by distance L₁ is (Vₜₒₚ−V_{mid})/L₁. The electric field in the space between middle electrode 54 and bottom electrode 58 is (V_{mid}−V_{bot})/L₂.

The MOTIS 10 may be situated halfway between Vₜₒₚ and V_{mid}. Accordingly, the beam energy may be expressed as follows after exiting the extraction electrodes 50, 54, and finally 58:

U_{beam}=e*(Vₜₒₚ−V_{mid}/2

where U_{beam} represents beam energy, e represents electron charge, Vₜₒₚ represents the voltage of the top electrode 50 and V_{mid} represents the voltage of the middle electrode 54. Optimization of the potentials and spacing between these electrodes 50, 54 and 58 may depend on the particular aberration coefficients of the elements in a given system.

After exiting the extraction electrodes 50, 54, 58, beam 20 may enter ion focusing column 60. An aperture 70 may be employed to define a hard edge for the virtual source size. Aperture 70 defines a size for the beam 20 as it enters the ion optical column 60.

The beam 20 may then enter a deflector 75. Such deflectors are well known in the art. An example of such a deflector is the double-octupole type described in U.S. Pat. No. 5,393,985. The deflector 75 may be programmed to direct the beam 20 to the area of the target surface 85 the user desires. Target surface 85 may be a substrate. Finally the beam 20 may pass through a three element lens 80 (or objective lens) which has its first and third elements 81, 83 grounded. Voltage Vₗₑₙₛ may be selected to focus the beam 20 at the target surface 85.

Secondary particles emitted by the target surface 85 in response to ion beam bombardment may be collected by a detector 90 such as a micro-channel plate or continuous dynode. The secondary particles collected by the detector may be used for imaging, particularly with an ion or electron microscope. The secondary particles detected may be any of the following: secondary electrons emitted from the surface, substrate secondary ions, or backscattered ions. Which of these will give the best signal will depend on the ionic species being employed, the beam energy, and the surface composition. An electron ‘flood gun’ may also be employed to aid in surface neutralization and improve secondary electron detection.

With the direct deposit and removal apparatus of the present disclosure, beam 20 may have the same energy when it strikes the surface as it does when leaving extraction electrode 58. If the extraction electrode geometry is held fixed with the three extraction electrodes 50, 54, 58, two of them having apertures and each of the voltages in the extraction electrodes are multiplied by a common factor a, then the ratio ΔU/U may remain unchanged.

If the voltages on the deflector and lens ion column elements are also multiplied by α, then the ion trajectories will also remain unchanged. This allows the user to change the beam energy to suit the task without shifting the beam on the target or changing the focal properties of the final lens. Additionally, since ΔU/U is unchanged, the chromatic aberration contribution to spot size will not depend on beam energy. This is markedly different from the performance of a liquid metal ion source (LMIS) or other emission source, which have fixed values for ΔU. In those systems, the chromatic aberration focal spot size contributions may grow inversely with the beam energy.

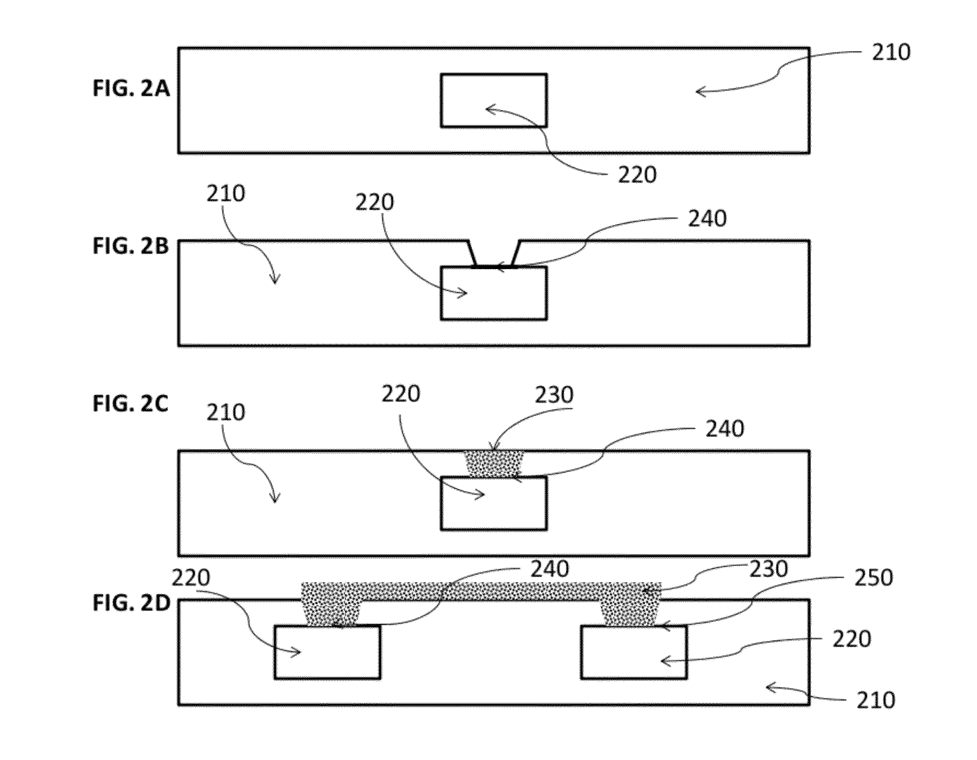

A conductive connection to a metal line buried beneath an insulating layer may be facilitated by the deposition and removal of nanoscale conductors. Referring now to FIGS. 2A-2C, illustrated are the steps required to create a conductive connection to a metal line buried beneath an insulating layer. Such a conductive connection may prove useful when using the apparatus of the present disclosure in the field of circuit editing. In a first step as shown in FIG. 2A, the area to be edited may be imaged with a medium to high energy beam (e.g., >1 keV). Then a high energy beam (e.g., >2 keV) may be concentrated in an area above the metal line 240 to which the connection will be made. The high energy beam may sputter away the insulating material 210. During this process, the image can be monitored and milling should be stopped once the metal line 240 has been uncovered (2B). The ion beam can then be switched into a low energy mode (e.g., <0.5 keV) and concentrated in the same region to fill the trench with the atomic species from the ion beam (2C). The process can be repeated above a different metal line 250, and the two connected with a conductive layer 220 deposited over the insulating top surface 210, if desired (2D).

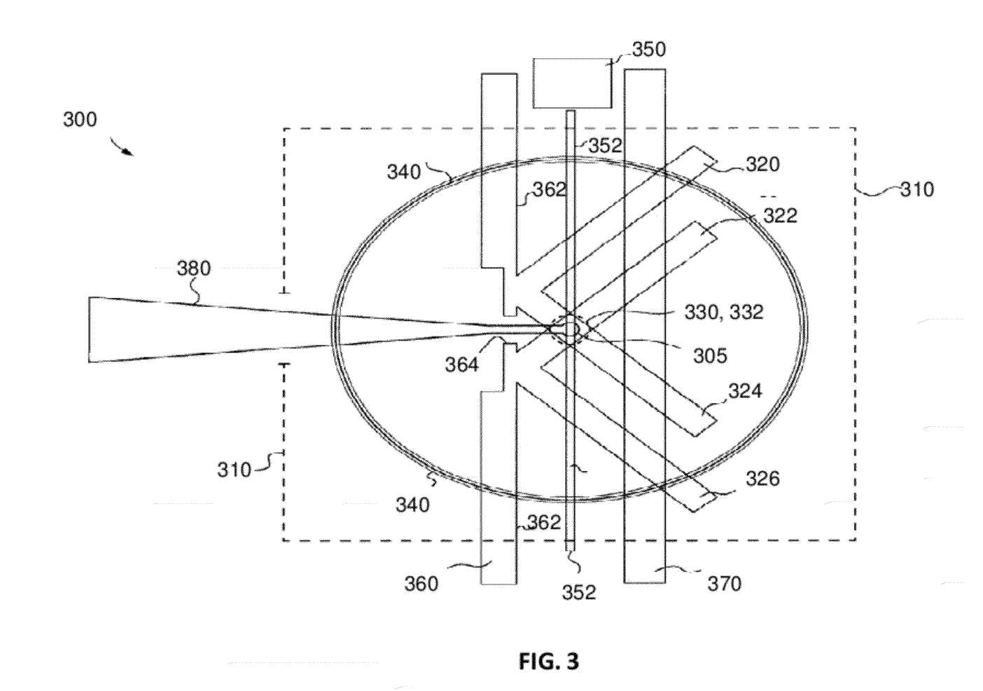

Referring now to FIG. 3, illustrated is a magneto-optical trap ion source in accordance with one embodiment of the invention. This MOTIS is also described in U.S. Pat. No. 7,709,807, which is assigned to the same assignee as the present invention and incorporated by reference herein. Ion source 300 may comprise a magneto-optical trap designated as dashed line 310. The magneto-optical trap may include a plurality of laser beams, e.g., the six laser beams 320, 322, 324, and 326 for cooling and trapping.

In this configuration of FIG. 3, two of the six laser beams project into and from the plane of the figure, and thus are depicted by the dashed circle and represented as items 330 and 332. The noted laser beams may be emitted from one or more lasers (not shown in FIG. 3). The six laser beams for the magneto-optical trap may be generally formed by one laser.

The magneto-optical trap may also comprise one or more components for providing a magnetic field, which as noted may be current carrying coils for producing the magnetic field, represented as 340 in FIG. 1. The coils can be disposed within a vacuum chamber of the magneto-optical trap. However, the present invention includes embodiments in which the coils are located outside of the vacuum chamber. The particular sizes and configuration of the laser beams and magnetic coils may depend upon the particular set up and characteristics desired for the magneto-optical trap. The laser beams 320, 322, 324, 326, 330, and 332, and the coils 340, serve to retain a cloud 305 of cold neutral atoms.

One or more permanent magnets for the component may provide the magnetic field. That is, instead of using coils through which electrical current is passed to generate magnetic field(s), one or more permanent magnets may be used instead of, or in conjunction with, the current carrying coils. The magnetic field providing component can use one or more permanent magnets or electromagnets, or combinations thereof.

The magneto-optical trap ion source 300 may further comprise an ionization laser 350 which emits a beam 352 as depicted in FIG. 1. The ionization laser 50 may be separate from the cooling and trapping laser beams 320, 322, 324, 326, 330, and 332. The orientation of the laser 350 and laser beam 352 emitted therefrom with respect to the other laser beams is not critical. However, it may be necessary that the laser beam 352 intersect the cloud 305 of cold atoms. The laser 352 may be focused to converge at a location inside the cloud 305 of cold atoms, but the present invention includes other configurations. The size of the laser beam 352 may depend upon the particular application. For example, a relatively tightly focused beam having a diameter of about 1 to 5 micrometers can be used for .low emittance applications. And, a relatively large focused beam, such as up to the size (i.e. diameter or span) of the cloud of atoms can be used for applications requiring high current and geometry characteristics.

The ionization laser 350 may be a separate unit from the laser of the magneto-optical trap. The ionization laser may use a wavelength significantly different from the wavelength of the cooling laser used in the trap. However, potentially for certain applications, it may be possible to use a laser beam from the trap, shift its wavelength, and then use the shifted wavelength beam as the ionization laser.

Instead of the extraction electrodes being separate from the magneto-optical trap ion source as described in FIG. 1, the extraction electrodes may be a part of the magneto-optical trap ion source as shown in FIG. 3. For example, the magneto-optical trap ion source 300 may comprise an extraction element, which may be an electrode assembly 360, 370. First electrode 360 may have a reflective layer 362. An aperture 364 may also be included. Electrode 360 may be maintained or may be otherwise in electrical communication with ground. Electrode 360 may include a reflective layer 362 in order to reflect laser beams 320, 322, 324, and 326. The electrode assembly may also include a second electrode 370 that may be transparent or substantially so. Electrode 370 may be maintained or held at some electrical bias potential. This potential depends upon the particular application. For example, a positive potential may be used to extract ions and a negative potential may be used to extract electrons. However, it may include any configuration in which two or more electrodes are appropriately electrically biased such that the resulting electric field extracts ions from the system.

Electrode 370 may be transparent or substantially so because the laser beams 320, 322, 324, and 326 may pass through the electrode 370. However, in the present configuration, none or only a portion of these lasers pass through the electrode 370. Electrode 370 may be in the form of a silica window coated with indium tin oxide (ITO), a transparent electrical conductor. Electrodes 360, 370 may be disposed within the vacuum chamber of the magneto-optical trap. The extraction element can be in nearly any form. If one or more electrodes are used for the extraction element, the electrodes can be in nearly any configuration. Generally, any arrangement that creates an extraction electric field is suitable. In this embodiment, the vacuum chamber may be maintained at ground potential and the single electrode may be held at a negative electrical potential to thereby extract ions. In other embodiments, two electrodes may be used so that one of the electrodes is held at ground while the other electrode is held at a positive potential to thereby create an electric field that extracts ions. The present disclosure includes the use of one, two, or more appropriately biased electrodes to extract ions from within the system.

Beam 380 may pass through the aperture 364 defined in the electrode 360 and propagate outward as desired.

While the specification describes particular embodiments of the present invention, those of ordinary skill can devise variations of the present invention without departing from the inventive concept.

We claim:

1. An apparatus for direct deposit and removal of nanoscale conductors on a target surface, the apparatus comprising:
a focused ion beam source, including a magneto-optical trap ion source;
a beam energy control device configured to selectively and controllably produce a low energy beam, the beam energy control device being further configured to selectively and controllably produce a high energy beam;
an ion-optical column configured to receive the beam from the beam energy control device and direct the low energy beam onto the target surface in order to deposit nanoscale conductive material onto the target surface, the ion optical column being further configured to direct the high energy beam onto the target surface in order to remove nanoscale conductive material from the target surface.

2. The apparatus of claim 1, wherein the beam energy control device includes a top electrode, a middle electrode and a bottom electrode, and wherein the middle electrode has a first aperture disposed therethrough and the bottom electrode has a second aperture disposed therethrough, and wherein the beam passes through the first and second apertures.

3. The apparatus of claim 1, wherein the ion optical column includes a deflector configured to direct the beam to a particular area of the target surface.

4. The apparatus of claim 1, wherein the ion optical column includes an aperture configured to define a size for the beam.

5. The apparatus of claim 1, wherein the conductive material is lithium, sodium, potassium, rubidium, cesium, magnesium, calcium, strontium, barium, chromium, silver, erbium, aluminum, dysprosium or ytterbium.

6. The apparatus of claim 1, wherein the ion optical column further comprises a three-element objective lens, the objective lens having its first and third elements grounded, the objective lens further having a voltage configured to focus the beam at the target surface.

7. The apparatus of claim 1, wherein the ion optical column further comprises a detector configured to collect secondary particles emitted by the substrate in response to receiving the beam.

8. The apparatus of claim 7, wherein the detector is a micro-channel plate or continuous dynode.

9. A method for direct deposit and removal of nanoscale conductors on a target surface, the method comprising the steps of:
providing a focused ion beam from a source that includes a magneto-optical trap ion source;
receiving the focused ion beam at a beam energy control device and selectively and controllably producing a low energy beam with the beam energy control device and/or selectively and controllably producing a high energy beam with the beam energy control device; and
directing the low energy beam from an ion optical column onto the target surface in order to deposit nanoscale conductive material onto the target surface, and/or directing the high energy beam from an ion optical column onto the target surface in order to remove nanoscale conductive material from the target surface.

10. The method of claim 9, wherein the beam energy control device includes a top electrode, a middle electrode and a bottom electrode, and wherein the middle electrode has a first aperture and the bottom electrode has a second aperture, and wherein the beam passes through the first and second apertures.

11. The method of claim 9, wherein the ion optical column includes a deflector configured to direct the beam to a particular area of the target surface.

12. The method of claim 9, wherein the ion optical column includes an aperture configured to define a size for the beam.

13. The method of claim 9, wherein the conductive material is lithium, sodium, potassium, rubidium, cesium, magnesium, calcium, strontium, barium, chromium, silver, erbium, aluminum, dysprosium or ytterbium.

14. The method of claim 9, wherein the ion optical column further comprises a three-element objective lens, the objective lens having its first and third elements grounded, the objective lens further having a voltage configured to focus the beam at the target surface.

15. The method of claim 9, wherein the ion optical column further comprises a detector configured to collect secondary particles emitted by the substrate in response to receiving the beam.

16. The method of claim 15, wherein the detector is a micro-channel plate or continuous dynode.
